(19) United States
(12) Patent Application Publication
(10) Pub. No.: US 2017/0168371 A1
(43) Pub. Date: Jun. 15, 2017

(54) MACH-ZEHNDER ELECTROOPTIC MODULATOR AND MANUFACTURING METHOD THEREOF

(71) Applicant: ELECTRONICS AND TELECOMMUNICATIONS RESEARCH INSTITUTE, Daejeon (KR)

(72) Inventors: Duk Jun KIM, Daejeon (KR); Young Ho KO, Daejeon (KR); Dong Young KIM, Daejeon (KR); Won Seok HAN, Daejeon (KR); Yong Hwan KWON, Daejeon (KR); Jong Hoi KIM, Daejeon (KR); Byung Seok CHOI, Daejeon (KR)

(73) Assignee: ELECTRONICS AND TELECOMMUNICATIONS RESEARCH INSTITUTE, Daejeon (KR)

(21) Appl. No.: 15/193,889

(22) Filed: Jun. 27, 2016

(30) Foreign Application Priority Data
Dec. 15, 2015 (KR) 10-2015-0178966

(51) Int. Cl. G02F 1/225; H01L 31/18

(52) U.S. Cl. CPC G02F 1/2257; H01L 31/184; G02F 2001/212

(57) ABSTRACT

There is provided a method for manufacturing a Mach-Zehnder electrooptic modulator including forming an intrinsic semiconductor layer including a Group III-V compound semiconductor on a Group III-V compound semiconductor substrate having an active region and a passive region, doping a first impurity in the intrinsic semiconductor layer corresponding to the active region to form a core layer disposed on the substrate and undoped with the first impurity and an upper clad layer disposed on the core layer and including a region doped with the first impurity, and patterning the core layer and the upper clad layer.

### CROSS-REFERENCE TO RELATED APPLICATION

The present application claims priority to Korean patent application number 10-2015-0178966 filed on Dec. 15, 2015 the entire disclosure of which is incorporated herein in its entirety by reference.

### BACKGROUND

1. Field

An embodiment of the present invention relates to a Mach-Zehnder electrooptic modulator and a manufacturing method thereof.

2. Description of the Related Art

A planar type optical waveguide element may control a phase of a guided wave by adjusting an effective refractive index of a waveguide.

Among the planar type optical waveguide elements, an optical waveguide element using an electrooptic effect is an element operated using a change in a refractive index of a core layer and a clad layer constituting an optical waveguide by applying an electric field between the optical waveguides. A Mach-Zehnder electrooptic modulator is known as the optical waveguide element using the electrooptic effect.

In the Mach-Zehnder electrooptic modulator, thicknesses of the core layer and the clad layer should be uniform in order to prevent loss of light. That is, when thicknesses of the core layer and the clad layer are uninformed, loss of light may occur in regions where the thicknesses are not uniform. When a plurality of regions in which the thicknesses are not uniform exist, a large amount of light loss may occur.

### SUMMARY

An embodiment of the present invention provides a Mach-Zehnder electrooptic modulator in which thicknesses of a clad layer are uniform.

Another embodiment of the present invention provides a method for manufacturing a Mach-Zehnder electrooptic modulator capable of making thicknesses of a clad layer uniform.

A method for manufacturing a Mach-Zehnder electrooptic modulator according to an embodiment of the present invention includes: forming an intrinsic semiconductor layer including a Group III-V compound semiconductor on a Group III-V compound semiconductor substrate having an active region and a passive region; doping a first impurity in the intrinsic semiconductor layer corresponding to the active region to form a core layer disposed on the substrate and undoped with the first impurity and an upper clad layer disposed on the core layer and including a region doped with the first impurity; and patterning the core layer and the upper clad layer. The core layer includes an active core layer disposed in the active region and a passive core layer disposed in the passive region, the upper clad layer includes an active upper clad layer disposed on the active core layer and doped with the first impurity and a passive upper clad layer disposed on the passive core layer and undoped with the first impurity, and the active upper clad layer and the passive upper clad layer have the same thickness.

The substrate may have a state of being doped with a second impurity, and a polarity of the second impurity may be opposite to a polarity of the active upper clad layer.

The method may further include: forming a lower clad layer including a Group III-V compound semiconductor disposed between the substrate and the intrinsic semiconductor layer.

A polarity of the first impurity may be opposite to a polarity of the lower clad layer.

The lower clad layer may include a Group III-V compound semiconductor material doped with an N-type impurity, and the first impurity may be a P-type impurity.

A Mach-Zehnder electrooptic modulator according to another embodiment of the present invention includes: a core layer disposed on a Group III-V compound semiconductor substrate having an active region and a passive region and including an active core layer and a passive core layer including Group III-V compound semiconductor; and an upper clad layer including a Group III-V compound semiconductor disposed on the core layer, wherein the upper clad layer includes an active upper clad layer disposed on the active core layer and doped with the first impurity and a passive upper clad layer disposed on the passive core layer and undoped with the first impurity, and the active upper clad layer and the passive upper clad layer may have the same thickness.

The method for manufacturing a Mach-Zehnder electrooptic modulator as described above may make a thickness of the clad layer uniform. In particular, the method for manufacturing a Mach-Zehnder electrooptic modulator may uniform thicknesses of an active region and a passive region of an upper clad layer, thus preventing loss of light guided in the Mach-Zehnder electrooptic modulator.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will full convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a plan view illustrating a Mach-Zehnder electrooptic modulator according to an embodiment of the present invention;

FIG. 2 is a perspective view illustrating a phase shifter illustrated in FIG. 1; and

FIGS. 3 to 6 are perspective views illustrating a process of a method for manufacturing the Mach-Zehnder electrooptic modulator illustrated in FIGS. 1 and 2.

### DETAILED DESCRIPTION

Hereinafter, embodiments will be described in greater detail with reference to the accompanying drawings. Embodiments are described herein with reference to cross-sectional illustrations that are schematic illustrations of embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements.

Terms such as ‘first’ and ‘second’ may be used to describe various components, but they should not limit the various components. Those terms are only used for the purpose of differentiating a component from other components. For example, a first component may be referred to as a second component, and a second component may be referred to as a first component and so forth without departing from the spirit and scope of the present invention. Furthermore, ‘and/or’ may include any one of or a combination of the components mentioned.

Furthermore, ‘connected/accessed’ represents that one component is directly connected or accessed to another component or indirectly connected or accessed through another component.

In this specification, a singular form may include a plural form as long as it is not specifically mentioned otherwise in a sentence. Furthermore, ‘include/comprise’ or ‘including/comprising’ used in the specification represents that one or more components, steps, operations, and elements exist or are added.

Furthermore, unless defined otherwise, all the terms used in this specification including technical and scientific terms have the same meanings as would be generally understood by those skilled in the related art. The terms defined in generally used dictionaries should be construed as having the same meanings as would be construed in the context of the related art, and unless clearly defined otherwise in this specification, should not be construed as having idealistic or overly formal meanings.

Example embodiments will now be described more fully hereinafter with reference to the accompanying drawings.

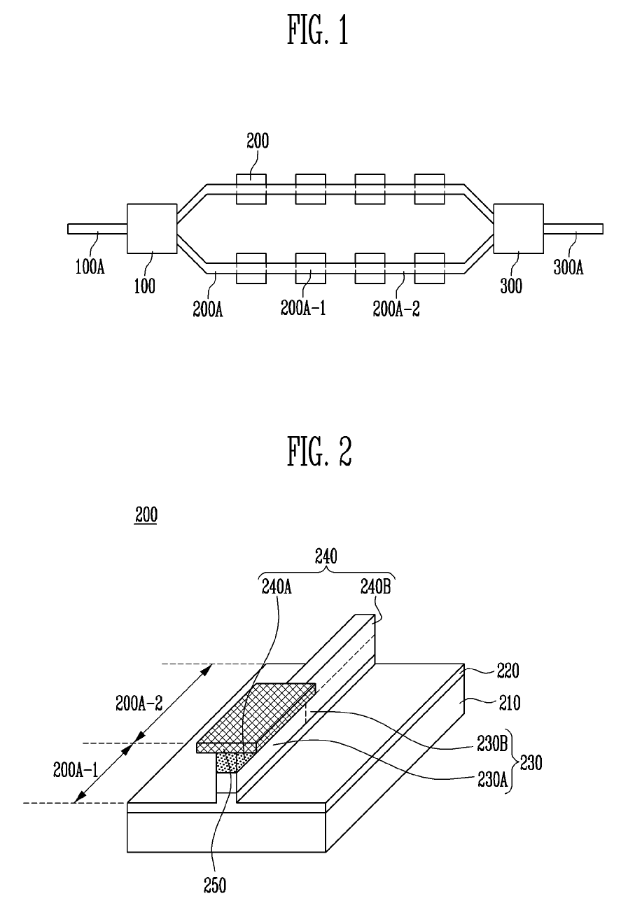

FIG. 1 is a plan view illustrating a Mach-Zehnder electrooptic modulator according to an embodiment of the present invention.

Referring to FIG. 1, the Mach-Zehnder electrooptic modulator may include an optical splitting unit 100, a phase shifter 200, and an optical coupling unit 300.

The optical splitting unit 100 may receive an input optical signal through an input optical wave guide 100A. Also, the optical splitting unit 100 may split the input optical signal into two split optical signals having the same phase.

The split optical signals may be input to the phase shifter 200 through arm waveguides 200A. The arm waveguides 200A may be classified into an active region 200A-1 and a passive region 200A-2.

The phase shifter 200 may be disposed in the active region 200A-1. Also, the phase shifter 200 may shift a phase of the split optical signals transmitted through the arm waveguides 200A. For example, the phase shifter 200 may control a phase difference of the split optical signals to be n times (n is a natural number) of π.

The optical coupling unit 300 may couple the split optical signals having a shifted phase to generate an output optical signal, and output the output optical signal to an output optical waveguide 300A.

The output optical signal generated by the optical coupling unit 300 may be a signal modulated in phase and intensity compared with the input optical signal through constructive interference or destructive interference.

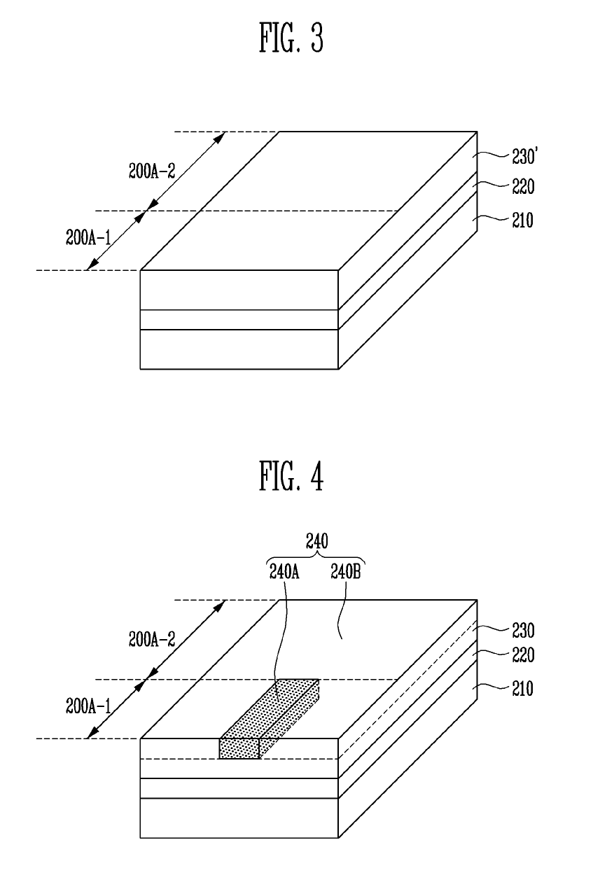

FIG. 2 is a perspective view illustrating a phase shifter illustrated in FIG. 1.

Referring to FIGS. 1 and 2, in a region in which the arm waveguide 200A is disposed, the Mach-Zehnder electrooptic modulator may include a waveguide disposed on a substrate 210 and a phase shifter 200 changing a refractive index of the waveguide by applying an electric field to the waveguide.

The waveguide may include a lower clad layer 220 disposed on the substrate 210, a core layer 230 disposed on the lower clad layer 220, and an upper clad layer 240 disposed on the core layer 230.

The substrate 210 may include an active region 200A-1 and a passive region 200A-2. Also, the substrate 210 may be a semiconductor substrate. For example, the substrate 210 may be a single crystal substrate including a Group III-V compound semiconductor including InP or GaAs.

The lower clad layer 220 may be disposed on the substrate 210. The lower clad layer 220 may include a semiconductor material, for example, the same material as that of the substrate 210. The lower clad layer 220 may be doped with an impurity, for example, an N-type impurity to have a predetermined charge carrier concentration. The N-type impurity may be silicon (Si).

On the other hand, the lower clad layer 220 may be omitted. In this case, the substrate 210 may be an N-type substrate doped with an N-type impurity. The substrate 210 may serve as the lower clad layer 220.

The core layer 230 may be an intrinsic semiconductor layer, and may be an optical waveguide in which light is transmitted. The core layer 230 may have an active core layer 230A disposed in the active region 200A-1 and a passive core layer 230B disposed in the passive region 200A-2.

The upper clad layer 240 may include an active upper clad layer 240A disposed on the active core layer 230A and a passive upper clad layer 240B disposed on the passive core layer 230B. The active upper clad layer 240A may be a region doped with a P-type impurity, for example, zinc (Zn). The passive upper clad layer 240B may be an intrinsic semiconductor region undoped with the P-type impurity. The active upper clad layer 240A and the passive upper clad layer 240B may have the same thickness.

In general, the active upper clad layer 240A and the passive upper clad layer 240B are formed through different processes and thicknesses of the active upper clad layer 240A may be different from thicknesses of the passive upper clad layer 240B. Light may be lost due to the difference in thickness of the waveguide in the boundary between the active upper clad layer 240A and the passive upper clad layer 240B. Thus, preferably, the thicknesses of the active upper clad layer 240A and the passive upper clad layer 240B are the same.

The phase shifter 200 may include an N-type electrode (not shown) connected to the lower clad layer 220 and a P-type electrode 250 connected to the active upper clad layer 240A. The P-type electrode 250 may be disposed on the active upper clad layer 240A.

When an electrical power supply is connected to the P-type electrode 250 and the N-type electrode, an electric field may be formed in the active core layer 230A between the lower clad layer 220 and the active upper clad layer 240A. The electric field may change a refractive index of the active core layer 230A to change a phase of the light.

The phase shifter 200 may control a phase difference of the split optical signals to be n times (n is a natural number) of π by adjusting the electric field.

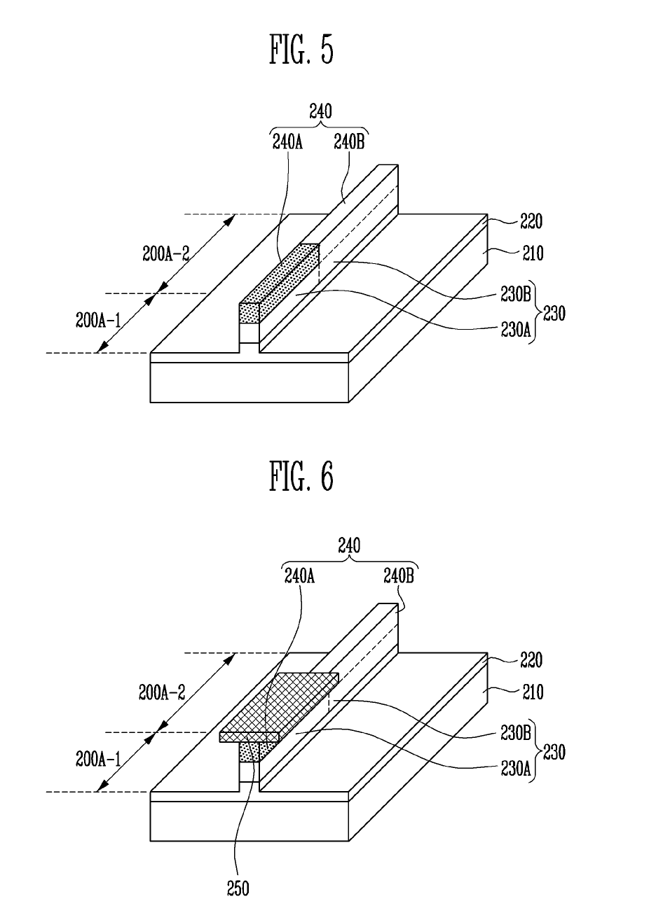

FIGS. 3 to 6 are perspective views illustrating a process of a method for manufacturing the Mach-Zehnder electrooptic modulator illustrated in FIGS. 1 and 2.

Referring to FIG. 3, the substrate 210 including the active region 200A-1 and the passive region 200A-2 is prepared. The substrate 210 may be a silicon substrate, a Group III-V compound semiconductor substrate, or a glass substrate. When the substrate 210 is a Group III-V compound semiconductor substrate, the substrate 210 may include InP or GaAs. In this embodiment, a case in which the substrate 210 is a Group III-V compound semiconductor substrate will be described as an example.

After the substrate 210 is prepared, the lower clad layer 220 is formed on the substrate 210. The lower clad layer 220 may be formed through method of metal organic vapor phase epitaxy (MOVPE), or method of molecular beam epitaxy (MBE).

The lower clad layer 220 may include a Group III-V compound semiconductor material, for example, the same material as that of the substrate 210. The lower clad layer 220 may be doped with an impurity, for example, an N-type impurity, to have a predetermined charge carrier concentration. The N-type impurity may be silicon (Si). The lower clad layer 220 may be electrically connected to the N-type electrode (not shown).

On the other hand, when the substrate 210 is an N-type substrate doped with an N-type impurity, the lower clad layer 220 may be omitted. That is, the substrate 210 itself may serve as the lower clad layer 220. The substrate 210 may be electrically connected to the N-type electrode.

After the lower clad layer 220 is formed, an intrinsic semiconductor layer 230′ is formed on the lower clad layer 220. The intrinsic semiconductor layer 230′ may include the same material as that of the lower clad layer 220. That is, the intrinsic semiconductor layer 230′ may include a Group III-V compound semiconductor material.

Also, the intrinsic semiconductor layer 230′ may be formed through the same method as that of the lower clad layer 220. For example, the intrinsic semiconductor layer 230′ may be formed through MOVPE or MBE.

Referring to FIG. 4, after the intrinsic semiconductor layer 230′ is formed, an impurity is doped in the intrinsic semiconductor layer 230′ corresponding to the active region 200A-1. The impurity may be a P-type impurity having a polarity opposite to that of the N-type impurity. For example, the impurity may be zinc (Zn). The P-type impurity may be doped through diffusion or ion implantation.

A depth in which the impurity is doped in the intrinsic semiconductor layer 230′ may be smaller than a thickness of the intrinsic semiconductor layer 230′. For example, a depth in which the impurity is doped in the intrinsic semiconductor layer 230′ may be ½ of the thickness of the intrinsic semiconductor layer 230′.

Through the impurity doping, the intrinsic semiconductor layer 230′ may be classified into a core layer 230 disposed on the lower clad layer 220, in which an impurity is not implanted, and an upper clad layer 240 disposed on the core layer 230.

The core layer 230 may include an active core layer 230A corresponding to the active region 200A-1 and a passive core layer 230B corresponding to the passive region 200A-2.

The upper clad layer 240 may include an active upper clad layer 240A disposed in the active region 200A-1 and doped with the impurity and a passive upper clad layer 240B disposed in the passive region 200A-2 and undoped with an impurity. Here, since the active upper clad layer 240A and the passive upper clad layer 240B are formed through impurity doping, the active upper clad layer 240A and the passive upper clad layer 240B may have a same thickness.

Referring to FIG. 5, after the impurity is doped, a portion of the lower clad layer 220, the core layer 230, and the upper clad layer 240 are simultaneously patterned. The patterning may be performed through a wet etching or dry etching process.

Also, through patterning, the core layer 230 may include an active core layer 230A corresponding to the active region 200A-1 and a passive core layer 230B corresponding to the passive region 200A-2.

Referring to FIG. 6, after the patterning process is performed, a P-type electrode 250 is formed on the active upper clad layer 240A.

As described above, the active upper clad layer 240A and the passive upper clad layer 240B may have the same thickness. This is because, the active upper clad layer 240A and the passive upper clad layer 240B are not formed through different processes but the upper clad layer 240 is classified into the active upper clad layer 240A and the passive upper clad layer 240B through the impurity doping process. Thus, the Mach-Zehnder electrooptic modulator including the active upper clad layer 240A and the passive upper clad layer 240B may prevent loss of light due to non-uniformity of the thickness of the upper clad layer 240.

Also, since a separate process is not added to form the active upper clad layer 240A and the passive upper clad layer 240B, manufacturing cost of the Mach-Zehnder electrooptic modulator may be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A method for manufacturing a Mach-Zehnder electrooptic modulator, the method comprising:
forming an intrinsic semiconductor layer including a Group III-V compound semiconductor on a Group III-V compound semiconductor substrate having an active region and a passive region;
doping a first impurity in an upper portion of the intrinsic semiconductor layer corresponding to the active region, to thereby separate the intrinsic semiconductor layer into an upper clad layer at the upper portion of the intrinsic semiconductor layer and a core layer at a lower portion of the intrinsic semiconductor layer, the core layer being undoped with the first impurity; and
patterning the core layer and the upper clad layer to form
an active core region disposed in the active region and a passive core region disposed in the passive region, and
an active upper clad region disposed on the active core region and doped with the first impurity and a passive upper clad region disposed on the passive core region and undoped with the first impurity, the active and passive upper clad regions being aligned with the active and passive core regions, respectively, the active upper clad region and the passive upper clad region having a same thickness.

2. The method of claim 1, wherein the substrate has a state of being doped with a second impurity, and a polarity of the second impurity is opposite to a polarity of the active upper clad region.

3. The method of claim 2, wherein the second impurity is an N-type impurity.

4. The method of claim 1, further comprising forming a lower clad layer including a Group III-V compound semiconductor disposed between the substrate and the intrinsic semiconductor layer.

5. The method of claim 4, wherein a polarity of the first impurity is opposite to a polarity of an impurity in the lower clad layer.

6. The method of claim 5, wherein the lower clad layer includes a Group III-V compound semiconductor material doped with an N-type impurity, and the first impurity is a P-type impurity.

7. The method of claim 6, wherein the first impurity includes zinc (Zn).

8. A Mach-Zehnder electrooptic modulator, comprising:
a semiconductor substrate having an active region and a passive region;
a core layer disposed on the semiconductor substrate and including an active core region and a passive core region, the core layer being undoped with a first impurity, the active core region being formed on the active region and the passive core region being formed on the passive region; and
an upper clad layer disposed on the core layer, the upper clad layer including an active upper clad region disposed on the active core region and doped with the first impurity, and a passive upper clad region disposed on the passive core region and undoped with the first impurity, the active and passive upper clad regions being aligned with the active and passive core regions, respectively, the active upper clad region and the passive upper clad region having a same thickness.

9. The Mach-Zehnder electrooptic modulator of claim 8, wherein the substrate is doped with a second impurity having a polarity opposite to a polarity of the first impurity.

10. The Mach-Zehnder electrooptic modulator of claim 8, further comprising: a lower clad layer including a Group III-V compound semiconductor disposed between the substrate and the core.

11. The Mach-Zehnder electrooptic modulator of claim 10, wherein the first impurity is an impurity having a polarity opposite to a polarity of an impurity in the lower clad layer.

12. The Mach-Zehnder electrooptic modulator of claim 11, wherein the lower clad layer includes a semiconductor material doped with an N-type impurity, and the first impurity is a P-type impurity.

13. The method of claim 1, wherein the upper clad region and the core region overlap in a plan view thereof.

14. The Mach-Zehnder electrooptic modulator of claim 8, wherein the upper clad region and the core region overlap in a plan view thereof.

15. A Mach-Zehnder electrooptic modulator, comprising:
a semiconductor substrate having an active region and a passive region;
a core layer disposed on the semiconductor substrate, the core layer including an active core region and a passive core region, and being undoped with a first impurity, the active core region being disposed on the active region and the passive core region being disposed on the passive region; and
an upper clad layer disposed on the core layer, and including an active upper clad region disposed on the active core region and doped with the first impurity, and a passive upper clad region disposed on the passive core region and undoped with the first impurity, the active upper clad region and the passive upper clad region having a same thickness.
